(19) United States
(12) Patent Application Publication
(10) Pub. No.: US 2026/0088629 A1
(43) Pub. Date: Mar. 26, 2026

(54) DISPATCHING METHOD FOR POWER GENERATION AND CONSUMPTION OF HYDRO-WIND-PHOTOVOLTAIC SYSTEMS WITH METEOROLOGICAL DOWNSCALING

(71) Applicant: DALIAN UNIVERSITY OF TECHNOLOGY, Dalian (CN)

(72) Inventors: Jianjian SHEN, Dalian (CN); Yushu WU, Dalian (CN); Xihai GUO, Dalian (CN); Linsong GE, Dalian (CN); Chuntian CHENG, Dalian (CN)

(21) Appl. No.: 19/221,222

(22) Filed: May 28, 2025

Related U.S. Application Data
(63) Continuation of application No. PCT/CN2024/109109, filed on Aug. 1, 2024.

(51) Int. Cl. H02J 3/46; G01R 21/133; G06N 20/10

(52) U.S. Cl. CPC H02J 3/46; G01R 21/133; G06N 20/10; H02J 2101/24; H02J 2101/28; H02J 2101/40; H02J 2103/30

(57) ABSTRACT

The present invention belongs to the field of multi-energy complementary and coordinated operations, and discloses a dispatching method for power generation and consumption of hydro-wind-photovoltaic systems with meteorological downscaling. The support vector machine regression algorithm was adopted to identify different hydro-meteorological variable data, achieving high-resolution spatial downscaling through statistical modeling between observational data and meteorological variables. Wind and photovoltaic power generation profiles were derived using established empirical power curve models. Sequential peak-shaving operation modes were introduced to formulate the linkage equation between peak shaving and the consumption of hydropower, wind power, and photovoltaic power, thereby preventing the overestimation of energy consumption that typically arises from neglecting climate variability and short-term generation characteristics. Case studies were conducted using cascaded hydropower plants on Lancang River and wind and photovoltaic power stations located in the river's surrounding areas in Yunnan. The results show that the present invention can significantly reduce hydro-meteorological downscaling errors.

### TECHNICAL FIELD

The present invention belongs to the field of multi-energy complementary and coordinated operations, and relates to a dispatching method for power generation and consumption for hydro-wind-photovoltaic systems with meteorological downscaling.

### TECHNICAL BACKGROUND

With the rapid transformation towards green and low-carbon energy structure in China, the proportion of new energy sources, mainly wind and photovoltaic power, in the installed capacity of the power grid is increasing. This has made power system operations increasingly weather-sensitive. In particular, the power generation of various clean energy sources such as hydropower, wind and photovoltaic power is highly dependent on changes in meteorological factors at the physical level. In this case, it has become very important and necessary to conduct a refined assessment of the impact of complex climatic and meteorological conditions on the complementary and coordinated operations of multiple energy sources and the consumption of new energy.

At present, obtaining high-resolution meteorological conditions by using downscaling techniques for meteorological data is an important way to accurately reflect future climate change and improve the accuracy of data. There are two main scaling techniques for meteorological data, dynamic scaling and statistical scaling. Dynamic scaling obtains complete climate variables with spatial continuity from the physical level, but the complex model structure and extremely large amount of calculation cost limit its computational accuracy. Statistical scaling is to establish the statistical relationship between the observed data and the provided data for meteorological downscaling. This method is characterized by simple and intuitive principle, and a small amount of calculation cost. So, it has been widely applied (Wang S, Zhu J, Huang G, et al. Assessment of climate change impacts on energy capacity planning in Ontario, Canada using high-resolution regional climate model[J]. Journal of Cleaner Production, 2020, 274:123026). Among them, machine learning algorithms have advantages such as high accuracy, good applicability, and low risk of sudden changes, and are widely used in large-scale hydrological simulation statistical scaling. Moreover, they can obtain information from high-dimensional climate variables without the need to parse the local hydrological processes of specific areas in advance (Hu Baojian, Li Wei, Chen Chuanfa, et al., Improving the precipitation quality of GPM satellite remote sensing by using the space random forest method [J]. Journal of Remote Sensing, 2024, 28(02):414-425). In terms of the assessment of the consumption of new energy, the impact of climate change on clean energy systems is usually evaluated on a monthly or ten-day step. It is assumed that the inputs of the model, such as the inflow runoff and the power generation of new energy, remain unchanged during this period (Zhang Y, Cheng C, Yang T et al. Assessment of climate change impacts on the hydro-wind-solar energy supply system[J]. Renewable and Sustainable Energy Reviews, 2022, 162:112480). However, the power generation of new energy sources is highly intermittent, fluctuating and unpredictable within a day. Such characteristics cannot precisely reflect the short-term energy consumption pattern, thereby leading to inaccurate assessment results and making it difficult to apply.

To solve the above problems, the present invention proposes a dispatching method for power generation and consumption of hydro-wind-photovoltaic systems with meteorological downscaling. This method is tested by application to an engineering example composed of hydropower plants on a large river basin as well as wind and photovoltaic power stations located in its surrounding areas. The results show that the present invention can effectively reduce the error of hydrometeorology downscaling. The linkage formulation of hydropower, wind power and photovoltaic power consumption can describe the power generation law of hydropower, wind power and photovoltaic power more accurately, making the accuracy and reliability of dispatching results better.

### Invention Content

The present invention mainly solves a technical problem of power generation and consumption dispatching of hydro-wind-photovoltaic systems with meteorological downscaling. The aim is to improve the accuracy and reliability of the consumption dispatching results by precisely assessing the impact of complex climatic and meteorological conditions on the complementary and coordinated operations of multiple energy sources and the consumption of new energy.

Technical solution of the present invention is as follows:

A dispatching method for power generation and consumption of hydro-wind-photovoltaic systems with meteorological downscaling, including the following steps:
(1) Support vector machine regression is utilized to spatially scale down hydro-meteorological variable data to accurately reflect the impact of climate change on generations of hydropower, wind power and photovoltaic power stations.
(1.1) Select hydro-meteorological variables as the original data set: The variation of runoff into the reservoir of hydropower station in each period is mapped by using the precipitation, evaporation, surface temperature and soil moisture content in each period. The 10-meter wind speed in each period is used to predict the near-surface wind speed at the wind power and photovoltaic power stations in each period. The short-wave radiation on the surface and the surface temperature in each period are used to predict the radiation received by the solar panels of the photovoltaic power station and the ambient temperature in each period.
(1.2) Divide the original data set for hydro-meteorological variables: The original data is divided into the training set, validation set and test set in chronological order at a ratio of 6:2:2.
(1.3) Suppose the training set is {(xᵢ, yᵢ)}, i∈[1,N), where xᵢ is the large-scale hydro-meteorological variable data of different atmospheric circulation models, yᵢ is the actual data corresponding to the time, and N is the size of the data set; Equation (1) is used to express the linear regression decision surface function of SVR, where ω is the weight vector and b is the bias; A nonlinear transformation function φ(⋅) is used to map the input space to a high-dimensional feature space:

$$f ( x ) = ω φ ( x ) + b \qquad ( 1 )$$

(1.4) Establish an insensitive loss function of allowable prediction error ε for hydro-meteorological variables:

$${I}^{ε} ( {f}_{i} {y}_{i} ) = \{ \begin{matrix}0 , \vert {f}_{i} - {y}_{i} \vert \leq ε \\ \vert {f}_{i} - {y}_{i} \vert - ε , \vert {f}_{i} - {y}_{i} \vert > ε\end{matrix} \qquad ( 2 )$$

(1.5) With minimizing the structural risk of prediction errors for hydro-meteorological variables, the Python-sklearn program module is utilized to transform the problem of minimizing prediction errors into an equivalent quadratic convex programming problem under constraint (4).

$$Min ( \frac{1}{2} {‖ ω ‖}^{2} + C {\sum }_{i = 1}^{N} ( {ξ}_{i} + {ξ}_{i}^{*} ) ) \qquad ( 3 )$$

$$\{ \begin{matrix}{f}_{i} - {y}_{i} \leq ε + {ξ}_{i} , i = 1 , 2 , … , N \\ - {f}_{i} + {y}_{i} \leq ε + {ξ}_{i}^{*} , i = 1 , 2 , … , N \\ {ξ}_{i} \geq 0 , i = 1 , 2 , … , N \\ {ξ}_{i}^{*} \geq 0 , i = 1 , 2 , … , N\end{matrix} \qquad ( 4 )$$

### Where ξᵢ and

$${ξ}_{i}^{*}$$

are positive relaxation factors of the prediction error, ξᵢ denotes the degree of relaxation when the predicted value is higher than the true value, and

$${ξ}_{i}^{*}$$

represents the degree of relaxation when the predicted value is lower than the true value. C is a regularization penalty coefficient of the prediction error.
(2) p_{i,t} is set as the predicted values of hydro-meteorological variables of power station i at time period t; r_{i,t} is the observed values of hydro-meteorological variables of power station i at time period t; r̅_{i,t} is the maximum value of the observed values of hydro-meteorological variables of power station i at time period t; [symbol] is the minimum value of the observed values of hydro-meteorological variables of power station i at time period t. The differences between the observed and predicted series of hydro-meteorological variables on the test set are characterized by the normalized mean square root difference (NRMSE) and the relative square error (RSE) to evaluate the prediction performance. The smaller the index value, the better the model performance. The specific calculation formula is as follows:

$$NRMSE = \frac{\frac{\sqrt{{\sum }_{i = 1}^{n} {( {p}_{i , t} - {r}_{i , t} )}^{2}}}{n}}{( {r}_{i} - {r}_{i} )} \qquad ( 5 )$$

$$RSE = \frac{{\sum }_{i = 1}^{n} {( {p}_{i , t} - {r}_{i , t} )}^{2}}{{\sum }_{i = 1}^{n} ( {r}_{i} - {r}_{i} )} \qquad ( 6 )$$

Where p_{i,t} represents the predicted values of hydro-meteorological variables of power station i at time period t; r_{i,t} is the observed values of hydro-meteorological variables of power station i at time period 1; r̅_{i,t} is the maximum value of the observed values of hydro-meteorological variables of power station i at time period t; [symbol] is the minimum value of the observed values of hydro-meteorological variables of power station i at time period t.
(3) The hydro-meteorological variables for the power station are input, and empirical formulas for wind power generation and photovoltaic power generation are constructed. The Python programming language is used to import the downscaling data of future hydro-meteorological variables from Excel files. These downscaling data are further solved by the Python-math library to obtain the variation process of wind and solar output rates. The specific formula is as follows:

The empirical formula for wind power generation:

$${V}_{{n}_{w} , t}^{z} = {V}_{{n}_{w} , t}^{{z}_{surface}} [ \frac{ln ( z / {z}_{0} )}{ln ( {z}_{surface} / {z}_{0} )} ] \qquad ( 7 )$$

$$\{ \begin{matrix}{C}_{{n}_{w} , t}^{w} = {β}_{{n}_{w}}^{0} + {β}_{{n}_{w}}^{1} \cdot {V}_{{n}_{w}}^{z} + {β}_{{n}_{w}}^{2} \cdot {( {V}_{{n}_{w} , t}^{z} )}^{2} \\ + {β}_{{n}_{w}}^{3} \cdot {( {N}_{{n}_{w} , t}^{z} )}^{3} \\ {\underline{V}}_{{n}_{w}}^{z} \leq {V}_{{n}_{w} , t}^{z} \leq {\overline{V}}_{{n}_{w}}^{z}\end{matrix} \qquad ( 8 )$$

$${N}_{{n}_{w} , t}^{w} = {I}_{{n}_{w}}^{w} \cdot {C}_{{n}_{w} , t}^{w} \cdot Δ {t}_{m} \qquad ( 9 )$$

### Where

$${V}_{{n}_{w} , t}^{z}$$

is the wind speed at the height of z meters of the turbine of the wind power station, m/s;

$${\underline{V}}_{{n}_{w}}^{z} , {\overline{V}}_{{n}_{w}}^{z}$$

are the incoming wind speed and outgoing wind speed of the turbine in the wind power station, respectively, m/s;

$${V}_{{n}_{w} , t}^{{z}_{surface}}$$

is the near-surface wind speed at the location of the wind power station, m/s; z₀ is the surface roughness length, which is taken as 0.0002 m; The output rate of a wind power station

$${C}_{{n}_{w} , t}^{w}$$

is the ratio of generation output to installed capacity;

$${β}_{{n}_{w}}^{0} , {β}_{{n}_{w}}^{1} , {β}_{{n}_{w}}^{2} , {β}_{{n}_{w}}^{3}$$

are coefficients of the power generation function;

$${I}_{{n}_{w}}^{w}$$

is the installed capacity or the wind power station; Δtₘ is the number of hours in month m.

The empirical formula for photovoltaic power generation:

$$\{ \begin{matrix}{C}_{{n}_{pv} , t}^{p ν} = {P}_{{n}_{pv} , t}^{R} \cdot \frac{r s d {s}_{{n}_{pv}}}{r s d {s}_{S T C}} \\ {P}_{{n}_{pv} , t}^{R} = 1 + γ \cdot [ {Tas}_{{n}_{pv} , t}^{c e l l} - T a {s}_{S T C} ]\end{matrix} \qquad ( 10 )$$

$${N}_{{n}_{pv} , t}^{p v} = {I}_{{n}_{pv}}^{p v} \cdot {C}_{{n}_{pv} , t}^{p v} \cdot Δ {t}_{m} \qquad ( 11 )$$

Where

$${C}_{{n}_{pv} , t}^{p v}$$

represents the output rate of the photovoltaic power station;

$${P}_{{n}_{pv} , t}^{R}$$

is the performance ratio of solar panels; rsdsₙ_{ₚᵥ} is the surface radiation of photovoltaic power station nₚᵥ; rsds_{STC} is surface radiation under standard atmospheric pressure, rsds_{STC}=1000W*m²; γ is a coefficient of the empirical formula, γ=−0.005° C.⁻¹;

$${Tas}_{{n}_{pv} , t}^{c e l l}$$

is the temperature of the solar cell, which is affected by temperature, radiation and wind speed. Tas_{STC} is the ambient air temperature under standard atmospheric pressure, Tas_{STC}=25° C.;

$${I}_{{n}_{pv}}^{p v}$$

is the installed capacity of the photovoltaic power station.

$$T a {s}_{{n}_{pv} , t}^{c e l l} = {c}_{{n}_{pv}}^{0} + {c}_{{n}_{pv}}^{1} \cdot {Tas}_{{n}_{pv} , t} + {c}_{{n}_{pv}}^{2} \cdot {rsds}_{{n}_{pv} , t} + {c}_{{n}_{pv}}^{3} \cdot {V}_{{n}_{pv} , t} \qquad ( 12 )$$

### Where

$${c}_{{n}_{pv}}^{0} = 4.3 ° C . , {c}_{{n}_{pv}}^{1} = 0.9 \; 43 , {c}_{{n}_{pv}}^{2} = 0.028 ° C . \cdot {m}^{2} \cdot {W}^{1} , {c}_{{n}_{pv}}^{3} = - 1.528 ° C . \cdot s \cdot {m}^{1} ; Ta {s}_{{n}_{pv} , t}$$

is the ambient temperature at the photovoltaic power station nₚᵥ, ° C.; Vₙ_{ₚᵥ}_{,t} is the surface wind speed at the photovoltaic power station nₚᵥ, m/s.

(4) The hydrological and meteorological variables at each power station are taken as the characteristic input. The piecewise linear fitting method is adopted to construct the linkage equation for the consumption of hydropower, wind power and photovoltaic power, realizing the extraction of the complementary consumption relationship of hydropower, wind power and photovoltaic power. The specific expression is as follows:

$${\sum }_{{n}_{w} = 1}^{{N}_{w}} {N}_{{n}_{w} , m}^{w} + {\sum }_{{n}_{pv} = 1}^{{N}_{pv}} {N}_{{n}_{pv} , m}^{p v} = {f}_{{U}_{t}^{{load}_{u}}} ( {\sum }_{{n}_{h} = 1}^{{N}_{h}} {N}_{{n}_{h} , m}^{h} ) \qquad ( 13 )$$

### Where

$${f}_{{U}_{m}^{{load}_{u}}} ( )$$

represents the linkage function of hydropower, wind power, and photovoltaic power consumption, indicating the quantitative relationship of hydropower, wind power and photovoltaic power consumption in the scenario where the load is

$${U}_{m}^{{load}_{u}}$$

in month m. The Gurobi solver is taken as the modeling platform. The Python language is used to transform the above nonlinear model into a mixed integer linear programming. The influence relationship between the hydropower generation and the consumption scale of wind and photovoltaic power is determined. The specific influence includes four main stages:

Stage 1: Insufficient regulation capacity of hydropower restricts the consumption of wind and photovoltaic power. With the increase of hydropower generation, the flexibility of hydropower is enhanced, and the proportion of wind and photovoltaic power consumption shows an upward trend.

Stage 2: The hydropower regulation capacity can completely smooth out the fluctuations in wind and photovoltaic power generation and respond to the peak shaving demands of power grids. Thus, wind and solar resources can be fully consumed by power grids.

Stage 3: The channel capacity limits the bundled transmission generation of hydropower, wind and photovoltaic power. Thus, the proportion of wind and photovoltaic power consumption shows a downward trend with the increase of hydropower generation.

Stage 4: The hydropower generation will continue to increase until the capacity limit of the channel is exceeded, and the wind and solar photovoltaic power generation will no longer be able to be consumed.

The beneficial effects of the present invention: Compared with the monthly dispatching method, the dispatching method that coupled meteorological downscaling and energy consumption characteristics can effectively reduce the inaccuracy of energy consumption assessment, and the impact of associated climate change on clean energy power generation. This shows better reliability, practicability and reduces dispatching risks. Meteorological downscaling essentially refers to the precise prediction of hydro-meteorological variables at each power station. The downscaling method is used to obtain the required high-precision data for determining the impact on clean energy power generation. Thus, the generation fluctuation of wind and photovoltaic power stations can be described in detail. Meanwhile, the influence relationship between hydropower generation and wind and photovoltaic power consumption is established by introducing the linkage equation of hydropower, wind and photovoltaic power consumption. This approach prevents the overestimation of new energy consumption that typically occurs in traditional monthly dispatching methods due to climate variability, thereby enhancing the accuracy of consumption analysis.

### ILLUSTRATION DESCRIPTION

FIG. 1 is the whole solution framework of the method in present invention;

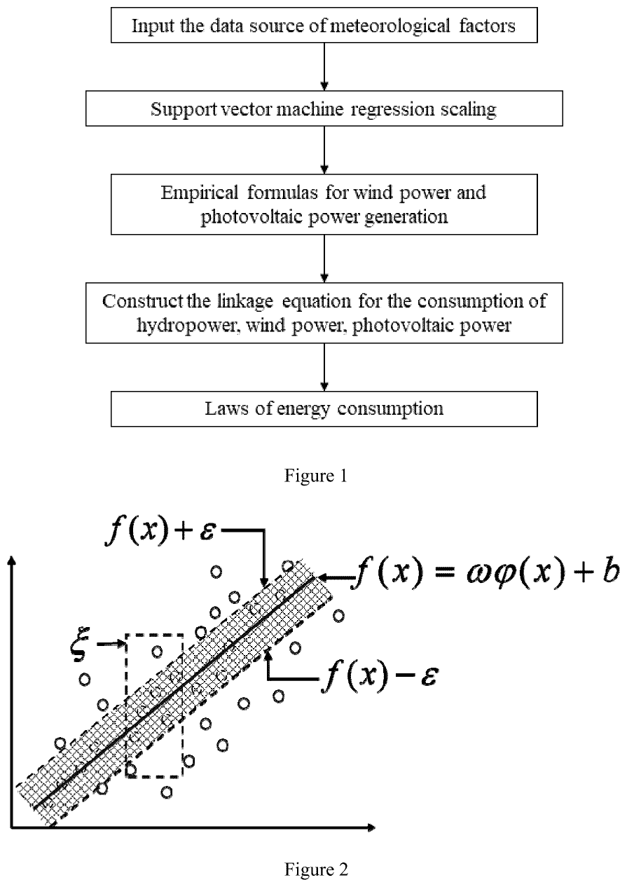

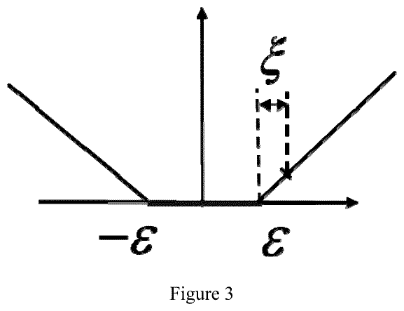

FIG. 2 is the principle of the support vector machine regression algorithm;

FIG. 3 is schematic diagram of error relaxation in the support vector machine regression algorithm;

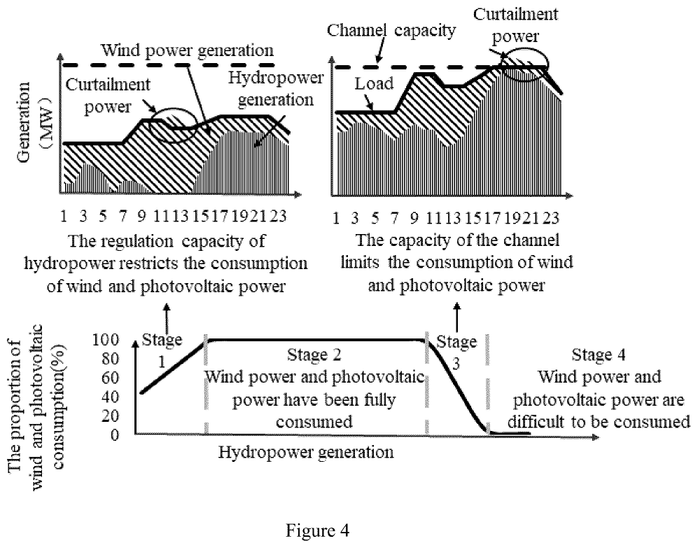

FIG. 4 is a schematic diagram of the consumption law of hydropower, wind power and photovoltaic power.

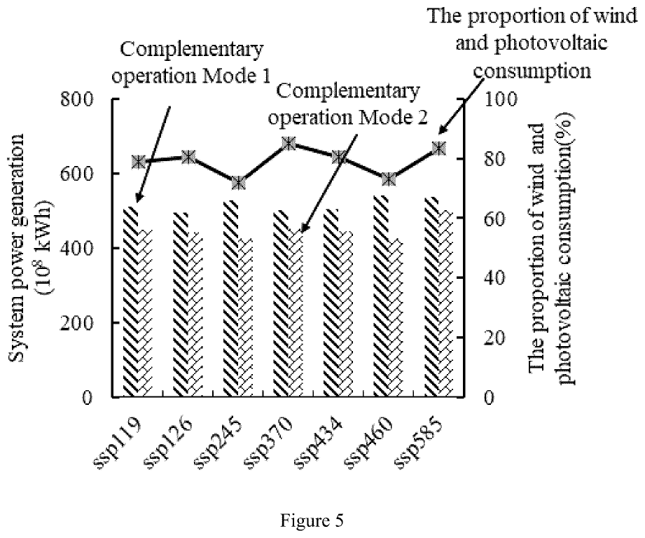

FIG. 5 is a schematic diagram of changes in power generation and consumption of the hydro-wind-photovoltaic system.

### SPECIFIC IMPLEMENTATION METHODS

The specific implementation procedure of the present invention is further described below according to the attached drawings and technical solutions.

The downscaling of meteorological data from hydropower, wind and photovoltaic clean energy systems is beneficial to more accurately reflect the impact of climate change on the power generation of various energy sources. To establish a statistical relationship between the observed data and the original data, hydrologic and meteorological variables are selected. The precipitation, evaporation, surface temperature and soil moisture content (0-35 cm) in each period are used to map the variation of runoff into the reservoir of hydropower station in each period. The 10-meter wind speed in each period is used to predict the near-surface wind speed at the wind power and photovoltaic power stations in each period. The short-wave radiation on the surface and the surface temperature in each period are used to predict the radiation received by solar panels of the photovoltaic power station and the ambient temperature in each period.

The historical data is then partitioned and divided into the training set, the validation set and the test set in chronological order at a ratio of 6:2:2. Among them, the training set is used to fit the model; the validation set is used for optimizing the hyperparameters of the model; and the test set is used to evaluate the performance of the trained model.

Suppose the training set is {(xᵢ, yᵢ)}, i∈[1, N), where xᵢ is the large-scale hydro-meteorological variable data of different atmospheric circulation models, yᵢ is the actual data corresponding to the time, and N is the size of the data set; Equation (1) is used to express the linear regression decision surface function of SVR, where ω is the weight vector and b is the bias; A nonlinear transformation function φ(⋅) is used to map the input space to a high-dimensional feature space:

$$f ( x ) = ω φ ( x ) + b \qquad ( 14 )$$

Subsequently, an insensitive loss function of allowable prediction error ε for hydro-meteorological variables is introduced:

$${I}^{ε} ( {f}_{i} {y}_{j} ) = \{ \begin{matrix}0 , \vert {f}_{i} - {y}_{i} \vert \leq ε \\ \vert {f}_{i} - {y}_{i} \vert - ε , \vert {f}_{i} - {y}_{i} \vert > 5\end{matrix} \qquad ( 15 )$$

As shown in FIG. 2, with minimizing the structural risk of prediction errors for hydro-meteorological variables, the Python-sklearn program module is utilized to transform the problem of minimizing prediction errors into an equivalent quadratic convex programming problem under constraint (17).

$$Min ( \frac{1}{2} {‖ ω ‖}^{2} + C {\sum }_{i = 1}^{N} ( {ξ}_{j} + {ξ}_{i}^{*} ) ) \qquad ( 16 )$$

$$\{ \begin{matrix}{f}_{i} - {y}_{i} \leq ε + {ξ}_{i} , i = 1 , 2 , … , N \\ - {f}_{i} + {y}_{i} \leq ε + {ξ}_{i}^{⋆} , i = 1 , 2 , … , N \\ {ξ}_{i} \geq 0 , i = 1 , 2 , … , N \\ {ξ}_{i}^{*} \geq 0 , i = 1 , 2 , … , N\end{matrix} \qquad ( 17 )$$

### Where ξᵢ and

$${ξ}_{i}^{*}$$

are positive relaxation factors of the prediction error, ξᵢ denotes the degree of relaxation when the predicted value is higher than the true value, and

$${ξ}_{i}^{*}$$

represents the degree of relaxation when the predicted value is lower than the true value. C is a regularization penalty coefficient of the prediction error. N is the sample size.

To measure the prediction accuracy of combination of different downscaling techniques and meteorological data sources, the normalized mean square root difference (NRMSE) and the relative square error (RSE) are used to characterize the differences between the observed and predicted series of hydro-meteorological variables on the test set, in order to reflect the effectiveness of downscaling techniques:

$$NRMSE = \frac{\sqrt{\frac{{\sum }_{i = 1}^{n} {( {p}_{i , t} - {r}_{i , t} )}^{2}}{n}}}{( {\overline{r}}_{i} - \underline{{r}_{i}} )} \qquad ( 18 )$$

$$RSE = \frac{{\sum }_{i = 1}^{n} {( {p}_{i , t} - {r}_{i , t} )}^{2}}{{\sum }_{i = 1}^{n} {( {\overline{r}}_{i , t} - {r}_{i , t} )}^{2}} \qquad ( 19 )$$

Where p_{i,t} represents the predicted values of hydro-meteorological variables of power station i at time period t; r_{i,t} is the observed values of hydro-meteorological variables of power station i at time period 1; r̅_{i,t} is the maximum value of the observed values of hydro-meteorological variables of power station i at time period t; [symbol] is the minimum value of the observed values of hydro-meteorological variables of power station i at time period t.

With empirical formulas of wind and solar power generation, the Python programming language is used to import the downscaling data of future hydro-meteorological variables from Excel files. These downscaling data are further solved by the Python-math library to obtain the variation process of wind and solar output rates. The wind power generation can be converted through empirical formulas. Moreover, it is reasonable for a polynomial power curve to approximate the wind power generation curve. The hourly wind speed at the hub height is the independent variable and the wind speed increases approximately logarithmically with the height. The empirical formula for wind power generation is as follows:

$${V}_{{n}_{w} , t}^{z} = {V}_{{n}_{w} , t}^{{z}_{surface}} [ \frac{ln ( z / {z}_{0} )}{ln ( {z}_{surface} {/}_{{Z}_{0}} )} ] \qquad ( 20 )$$

$$\{ \begin{matrix}{C}_{{n}_{w} , t}^{w} = {β}_{{n}_{w}}^{0} + {β}_{{n}_{w}}^{1} \cdot {V}_{{n}_{w}}^{z} + {β}_{{n}_{w}}^{2} \cdot {( {V}_{{n}_{w} , t}^{z} )}^{2} + {β}_{{n}_{w}}^{3} \cdot {( {V}_{{n}_{w} , t}^{z} )}^{3} \\ {\underline{V}}_{{n}_{w}}^{z} \leq {V}_{{n}_{w} , t}^{z} \leq {\overline{V}}_{{n}_{w}}^{z}\end{matrix} \qquad ( 21 )$$

$${N}_{{n}_{w} , t}^{w} = {I}_{{n}_{w}}^{w} \cdot {C}_{{n}_{w} , t}^{w} \cdot Δ {t}_{m} \qquad ( 22 )$$

### Where

$${V}_{{n}_{w} , t}^{z}$$

is the wind speed at the height of z meters of the turbine of the wind power station, m/s;

$${\underline{V}}_{{n}_{w}}^{z} , {\overline{V}}_{{n}_{w}}^{z}$$

are the incoming wind speed and outgoing wind speed of the turbine in the wind power station, respectively, m/s;

$${V}_{{n}_{w} , t}^{{z}_{surface}}$$

is the near-surface wind speed at the location of the wind power station, m/s; z₀ is the surface roughness length, which is taken as 0.0002 m; The output rate of a wind power station

$${C}_{{n}_{w} , t}^{w}$$

is the ratio of wind power station (that is the ratio of generation output to installed capacity;

$${β}_{{n}_{w}}^{0} , {β}_{{n}_{w}}^{1} , {β}_{{n}_{w}}^{2} , {β}_{{n}_{w}}^{3}$$

are coefficients of the power generation function;

$${I}_{{n}_{w}}^{w}$$

is the installed capacity of the wind power station; Δtₘ is the number of hours in month m.

Photovoltaic power stations generate electricity through solar cells, and their generation output rate can be expressed as an empirical function with environmental temperature and solar radiation as independent variables. The empirical formula for photovoltaic power generation is as follows:

$$\{ \begin{matrix}{C}_{{n}_{pv} , t}^{p ν} = {P}_{{n}_{pv ,} t}^{R} \cdot \frac{{rsds}_{{n}_{pv}}}{{rsds}_{STC}} \\ {P}_{{n}_{pv} , t}^{R} = 1 + γ \cdot [ {Tas}_{{n}_{pv} , t}^{cell} - {Tas}_{STC} ]\end{matrix} \qquad ( 23 )$$

$${N}_{{n}_{pv} , t}^{pv} = {I}_{{n}_{pν}}^{pv} \cdot {C}_{{n}_{pv} , t}^{pv} \cdot Δ {t}_{m} \qquad ( 24 )$$

### Where

$${C}_{{n}_{pv} , t}^{p v}$$

represents the output rate of the photovoltaic power station;

$${P}_{{n}_{pv} , t}^{R}$$

is the performance ratio of solar panels; rsdsₙ_{ₚᵥ} is the surface radiation of photovoltaic power station nₚᵥ; rsds_{STC} is surface radiation under standard atmospheric pressure (101.325 kPa), rsds_{STC}=1000W*m₂; γ is a coefficient of the empirical formula, γ=−0.005° C.⁻¹;

$${Tas}_{{n}_{pv} , t}^{cell}$$

is the temperature of the solar cell, which is affected by temperature, radiation and wind speed. Tas_{STC} is the ambient air temperature under standard atmospheric pressure (101.325 kPa), Tas_{STC}=25° C.;

$${I}_{{n}_{pv}}^{p v}$$

is the installed capacity of the photovoltaic power station.

$${Tas}_{{n}_{pv} , t}^{cell} = {c}_{{n}_{pv}}^{0} + {c}_{{n}_{pv} , t}^{1} \cdot {Tas}_{{n}_{pv} , t} + {c}_{{n}_{pv}}^{2} \cdot {rsds}_{{n}_{pv} , t} + {c}_{{n}_{pv}}^{3} \cdot {V}_{{n}_{pv} , t} \qquad ( 25 )$$

### Where

$${c}_{{n}_{pv}}^{0} = 4.3 ° C . , {c}_{{n}_{pv}}^{1} = 0.9 \; 43 , {c}_{{n}_{pv}}^{1} = 0.028 ° C . \cdot {m}^{2} \cdot {W}^{1} , {c}_{{n}_{pv}}^{3} = - 1.528 ° C . \cdot s \cdot {m}^{- 1} ; {Tas}_{{n}_{pv} , t}$$

is the ambient temperature at the photovoltaic power station nₚᵥ, ° C.; Vₙ_{ₚᵥ}_{,t} is the surface wind speed at the photovoltaic power station nₚᵥ, m/s.

As shown in FIG. 4, the consumption laws of hydropower, wind and photovoltaic power can be extracted by taking advantage of the spatio-temporal complementary consumption characteristics among power sources. This can help to improve the accuracy of energy consumption assessment under climate change in dispatching simulations.

The hydrological and meteorological variables at each power station are taken as the characteristic input. The piecewise linear fitting method is adopted to construct the linkage equation for the consumption of hydropower, wind power and photovoltaic power, realizing the extraction of the complementary consumption relationship of hydropower, wind power and photovoltaic power. The Gurobi solver is taken as the modeling platform. The Python language is used to transform the above nonlinear model into a mixed integer linear programming. The influence relationship between the hydropower generation and the consumption scale of wind and photovoltaic power is determined.

To sum up, the expression of the linkage equation for the consumption of hydropower, wind power, and photovoltaic power is as follows:

$${\sum }_{{n}_{w} = 1}^{{N}_{w}} {N}_{{n}_{w} , m}^{w} + {\sum }_{{n}_{pv} = 1}^{{N}_{pv}} {N}_{{n}_{pv} , m}^{p ν} = {f}_{{U}_{t}^{{load}_{a}}} ( {\sum }_{{n}_{h} = 1}^{{N}_{h}} {N}_{{n}_{h} , m}^{h} ) \qquad ( 13 )$$

### Where

$${f}_{{U}_{m}^{{load}_{u}}} ( \cdot )$$

represents the linkage function of hydropower, wind power, and photovoltaic power consumption, indicating the quantitative relationship of hydropower, wind power and photovoltaic power consumption in the scenario where the load is

$${U}_{m}^{{load}_{u}}$$

in month m.

The introduction of the linkage equation for hydropower, wind power, and photovoltaic power consumption in monthly dispatching methods establishes the correlation between hydropower generation and the consumption of wind and photovoltaic power. This approach prevents the overestimation of new energy consumption in monthly dispatching caused by climate variability, thereby enhancing the rationality of dispatching analysis results.

A cascaded hydropower plants including LXW and LNZD with multi-yearly regulation capacity in an extra-large river and wind and photovoltaic power stations in its surrounding landscape are used to test the invention. The 2023 full-year hourly-resolution data for wind/photovoltaic power generation and river runoff were used as sample datasets. The load profiles of power grids, generation profiles of wind and photovoltaic power and historical data used in the present invention refer to actual operation data of power grids and power stations.

The calculation results are shown in Tables 1-4. Compared with other downscaling machine learning algorithms, the Support Vector Machine regression (SVR) algorithm maintains the highest prediction accuracy for future hydro-meteorological variables regardless of the originating GCM data source. Furthermore, FgoS-G3-SVR, MRI-ESM2-0-SVR, MIROC6-SVR, and CanESM5-SVR perform best in predicting solar radiation, environmental temperature, surface wind speed, and runoff, respectively. Different GCMs exhibit specific accuracy and reliability when predicting different hydro-meteorological variables. Therefore, combining SVR with the outputs of different GCMs in the prediction model can provide more accurate information about climate change.

When the peak shaving depth remains unchanged, the changes in the consumption of wind and photovoltaic power within a year conform to the natural variation trend of its resources. Moreover, in the complementary consumption characteristics of different months, the consumption of wind and photovoltaic power increases with the increase of hydropower generation. Paradoxically, increased hydropower generation may hinder wind and photovoltaic power consumption. This occurs because extreme hydropower generation variations (either excessive or insufficient) reduce system flexibility, limiting hydropower's ability to balance intermittent renewables.

To validate the accuracy of the proposed method in assessing hydropower, wind, and photovoltaic power utilization, we established two complementary operational modes. By accounting for current peak shaving requirements, we compared simulation results from: an independent operation model for each power source, and the two integrated complementary operation models. In traditional long-term dispatching models, the short-term complementary operation of non-nested base energy is defined as Complementary Operation Mode 1 (Mode 1). Conversely, the long-term scheduling model incorporating nested short-term complementary consumption characteristics is designated as Complementary Operation Mode 2 (Mode 2).

The results of two modes are shown in FIG. 5. The power generation of Mode 1 is generally higher than that of Mode 2. Under the SSP119 climate change path, the total energy consumption of Mode 2 only accounts for 72% of that of Model 1, and the average proportion of energy consumption under different climate changes is approximately 79%. This suggests that within conventional monthly dispatching frameworks, river basin operators assessing future energy generation under climate change impacts may ultimately fail to achieve projected benefits if they disregard short-term grid peak-shaving requirements. It can be known that ignoring short-term complementary characteristics of the hydropower-wind-photovoltaic complementary system under such a framework will lead to overly optimistic consumption assessment results. Such results could be amplified by the superimposed impacts of varying climate change conditions.

Through the comparative analysis of different algorithms and schemes, it is verified that the dispatching method for generation and consumption of hydropower, wind power and photovoltaic power system with meteorological downscaling proposed by the present invention can be applied to monthly dispatching frameworks and provide high-accuracy and strong-applicability results. This approach enables robust assessment of clean energy utilization efficiency under varying climatic and meteorological conditions.

TABLE 1
Prediction of solar radiation by combinations of output
data from different GCM models and downscaling techniques

| GCMs | | | | | | | | |
|---|---|---|---|---|---|---|---|---|
| Evaluation | CanESM5 | | FGOALS-g3 | | MIROC6 | | MRI-ESM2-0 | |
| index | NRMSE | RSE | NRMSE | RSE | NRMSE | RSE | NRMSE | RSE |
| SVR | 0.146 | 0.458 | 0.132 | 0.372 | 0.167 | 0.595 | 0.153 | 0.503 |
| KNN | 0.148 | 0.471 | 0.139 | 0.414 | 0.203 | 0.879 | 0.159 | 0.538 |
| XGBoost | 0.154 | 0.508 | 0.155 | 0.512 | 0.172 | 0.635 | 0.166 | 0.593 |

TABLE 2
Prediction of environmental temperature by combinations of output
data from different GCM models and downscaling techniques

| GCMs | | | | | | | | |
|---|---|---|---|---|---|---|---|---|
| Evaluation | CanESM5 | | FGOALS-g3 | | MIROC6 | | MRI-ESM2-0 | |
| index | NRMSE | RSE | NRMSE | RSE | NRMSE | RSE | NRMSE | RSE |
| SVR | 0.009 | 0.289 | 0.007 | 0.168 | 0.007 | 0.163 | 0.007 | 0.164 |
| KNN | 0.011 | 0.439 | 0.008 | 0.221 | 0.008 | 0.224 | 0.008 | 0.248 |
| XGBoost | 0.009 | 0.301 | 0.007 | 0.191 | 0.007 | 0.192 | 0.007 | 0.185 |

TABLE 3
Prediction of surface wind speed by combinations of output
data from different GCM models and downscaling techniques

| GCMs | | | | | | | | |
|---|---|---|---|---|---|---|---|---|
| Evaluation | CanESM5 | | FGOALS-g3 | | MIROC6 | | MRI-ESM2-0 | |
| index | NRMSE | RSE | NRMSE | RSE | NRMSE | RSE | NRMSE | RSE |
| SVR | 0.303 | 0.585 | 0.301 | 0.669 | 0.227 | 0.38 | 0.234 | 0.404 |
| KNN | 0.304 | 0.588 | 0.36 | 0.957 | 0.228 | 0.384 | 0.264 | 0.513 |
| XGBoost | 0.33 | 0.695 | 0.315 | 0.73 | 0.239 | 0.423 | 0.234 | 0.405 |

TABLE 4
Prediction of runoff by combinations of output data
from different GCM models and downscaling techniques

| GCMs | | | | | | | | |
|---|---|---|---|---|---|---|---|---|
| Evaluation | CanESM5 | | FGOALS-g3 | | MIROC6 | | MRI-ESM2-0 | |
| index | NRMSE | RSE | NRMSE | RSE | NRMSE | RSE | NRMSE | RSE |
| SVR | 0.352 | 0.253 | 0.366 | 0.273 | 0.353 | 0.255 | 0.354 | 0.256 |
| KNN | 0.359 | 0.263 | 0.369 | 0.278 | 0.359 | 0.263 | 0.366 | 0.273 |
| XGBoost | 0.354 | 0.257 | 0.372 | 0.283 | 0.361 | 0.257 | 0.352 | 0.272 |

1. A dispatching method for power generation and consumption of hydro-wind-photovoltaic systems with meteorological downscaling, characterized in that it includes the following steps:
(1) support vector machine regression is utilized to spatially scale down hydro-meteorological variable data to accurately reflect the impact of climate change on generations of hydropower, wind power and photovoltaic power stations;
(1.1) select hydro-meteorological variables as the original data set: The variation of runoff into the reservoir of hydropower station in each period is mapped by using the precipitation, evaporation, surface temperature and soil moisture content in each period; the 10-meter wind speed in each period is used to predict the near-surface wind speed at the wind power and photovoltaic power stations in each period; the short-wave radiation on the surface and the surface temperature in each period are used to predict the radiation received by the solar panels of the photovoltaic power station and the ambient temperature in each period;
(1.2) divide the original data set for hydro-meteorological variables: The original data is divided into the training set, validation set and test set in chronological order at a ratio of 6:2:2;
(1.3) suppose the training set is {(xᵢ, yᵢ)}, i∈[1, N), where xᵢ is the large-scale hydro-meteorological variable data of different atmospheric circulation models, yᵢ is the actual data corresponding to the time, and N is the size of the data set; Equation (1) is used to express the linear regression decision surface function of SVR, where ω is the weight vector and b is the bias; A nonlinear transformation function φ(⋅) is used to map the input space to a high-dimensional feature space:
$$f ( x ) = ω φ ( x ) + b \qquad ( 1 )$$
(1.4) establish an insensitive loss function of allowable prediction error ε for hydro-meteorological variables:
$${I}^{ε} ( {f}_{i} , {y}_{i} ) = \{ \begin{matrix}0 , \vert {f}_{i} - {y}_{i} \vert \leq ε \\ \vert {f}_{i} - {y}_{i} \vert - ε , \vert {f}_{i} - {y}_{i} \vert > ε\end{matrix} \qquad ( 2 )$$
(1.5) with minimizing the structural risk of prediction errors for hydro-meteorological variables, the Python-sklearn program module is utilized to transform the problem of minimizing prediction errors into an equivalent quadratic convex programming problem under constraint (4);
$$Min ( \frac{1}{2} {‖ ω ‖}^{2} + C {\sum }_{i = 1}^{N} ( {ξ}_{j} + {ξ}_{j}^{*} ) ) \qquad ( 3 )$$
$$\{ \begin{matrix}{f}_{i} - {y}_{i} \leq ε + {ξ}_{i} , i = 1 , 2 , … , N \\ - {f}_{i} + {y}_{i} \leq ε + {ξ}_{i}^{*} , i = 1 , 2 , … , N \\ {ξ}_{i} \geq 0 , i = 1 , 2 , … , N \\ {ξ}_{j}^{*} \geq 0 , i = 1 , 2 , … , N\end{matrix} \qquad ( 4 )$$
where ξᵢ and
$${ξ}_{i}^{*}$$
are positive relaxation factors of the prediction error, ξᵢ denotes the degree of relaxation when the predicted value is higher than the true value, and
$${ξ}_{i}^{*}$$
represents the degree of relaxation when the predicted value is lower than the true value; C is a regularization penalty coefficient of the prediction error;
(2) p_{i,t} is set as the predicted values of hydro-meteorological variables of power station i at time period t; r_{i,t} is the observed values of hydro-meteorological variables of power station i at time period t; r̅_{i,t} is the maximum value of the observed values of hydro-meteorological variables of power station i at time period t; [symbol] is the minimum value of the observed values of hydro-meteorological variables of power station i at time period t; the differences between the observed and predicted series of hydro-meteorological variables on the test set are characterized by the normalized mean square root difference (NRMSE) and the relative square error (RSE) to evaluate the prediction performance; the smaller the index value, the better the model performance; the specific calculation formula is as follows:
$$NRMSE = \frac{\sqrt{\frac{{\sum }_{i = 1}^{n} {( {p}_{i , t} - {r}_{i , t} )}^{2}}{n}}}{( {\overline{r}}_{i} - \underline{{r}_{i}} )} \qquad ( 5 )$$
$$RSE = \frac{{\sum }_{i = 1}^{n} {( {p}_{i , t} - {r}_{i , t} )}^{2}}{{\sum }_{i = 1}^{n} {( {\overline{r}}_{i , t} - {r}_{i , t} )}^{2}} \qquad ( 6 )$$
where p_{i,t} represents the predicted values of hydro-meteorological variables of power station i at time period t; r_{i,t} is the observed values of hydro-meteorological variables of power station i at time period t; r̅_{i,t} is the maximum value of the observed values of hydro-meteorological variables of power station i at time period t; [symbol] is the minimum value of the observed values of hydro-meteorological variables of power station i at time period t;
(3) the hydro-meteorological variables for the power station are input, and empirical formulas for wind power generation and photovoltaic power generation are constructed; the Python programming language is used to import the downscaling data of future hydro-meteorological variables from Excel files; these downscaling data are further solved by the Python-math library to obtain the variation process of wind and solar output rates; the specific formula is as follows:
the empirical formula for wind power generation:
$${V}_{{n}_{w} , t}^{z} = {V}_{{n}_{w} , t}^{{z}_{surface}} [ \frac{ln ( z / {z}_{0} )}{ln ( {z}_{surface} / {z}_{0} )} ] \qquad ( 7 )$$
$$\{ \begin{matrix}{C}_{{n}_{w} , t}^{w} = {β}_{{n}_{w}}^{0} + {β}_{{n}_{w}}^{1} \cdot {V}_{{n}_{w}}^{z} + {β}_{{n}_{w}}^{2} \cdot {( {V}_{{n}_{w} , t}^{z} )}^{2} \\ + {β}_{{n}_{w}}^{3} \cdot {( {V}_{{n}_{w} , t}^{z} )}^{3} \\ \\ {\underline{V}}_{{n}_{w}}^{z} \leq {V}_{{n}_{w} , t}^{z} \leq {\overline{V}}_{{n}_{w}}^{z}\end{matrix} \qquad ( 8 )$$
$${N}_{{n}_{w} , t}^{w} = {I}_{{n}_{w}}^{w} \cdot {C}_{{n}_{w} , t}^{w} \cdot Δ {t}_{m} \qquad ( 9 )$$
where
$${V}_{{n}_{w} , t}^{z}$$
is the wind speed at the height of z meters of the turbine of the wind power station, m/s;
$${\underline{V}}_{{n}_{w}}^{z} , {\overline{V}}_{{n}_{w}}^{z}$$
are the incoming wind speed and outgoing wind speed of the turbine in the wind power station, respectively, m/s;
$${V}_{{n}_{w} , t}^{{z}_{surface}}$$
is the near-surface wind speed at the location of the wind power station, m/s; z₀ is the surface roughness length, which is taken as 0.0002 m; The output rate of a wind power station
$${C}_{{n}_{w} , t}^{w}$$
is the ratio of generation output to installed capacity;
$${β}_{{n}_{w}}^{0} , {β}_{{n}_{w}}^{1} , {β}_{{n}_{w}}^{2} , {β}_{{n}_{w}}^{3}$$
are coefficients of the power generation function;
$${I}_{{n}_{w}}^{w}$$
is the installed capacity of the wind power station; Δtₘ is the number of hours in month m;
the empirical formula for photovoltaic power generation:
$$\{ \begin{matrix}{C}_{{n}_{pv} , t}^{pv} = {P}_{{n}_{pv} , t}^{R} \cdot \frac{{rsds}_{{n}_{pv}}}{{rsds}_{STC}} \\ {P}_{{n}_{pv} , t}^{R} = 1 + γ \cdot [ {Tas}_{{n}_{pv} , t}^{cell} - {Tas}_{STC} ]\end{matrix} \qquad ( 10 )$$
$${N}_{{n}_{pv} , t}^{pv} = {I}_{{n}_{pv}}^{pv} \cdot {C}_{{n}_{pv} , t}^{pv} \cdot Δ {t}_{m} \qquad ( 11 )$$
where
$${C}_{{n}_{pv} , t}^{pv}$$
represents the output rate of the photovoltaic power station,
$${P}_{{n}_{pv} , t}^{R}$$
is the performance ratio of solar panels; rsdsₙ_{ₚᵥ} is the surface radiation of photovoltaic power station nₚᵥ; rsds_{STC} is surface radiation under standard atmospheric pressure, rsds_{STC}=1000W*m²; γ is a coefficient of the empirical formula, γ=−0.005° C.⁻¹;
$${Tas}_{{n}_{pv} , t}^{cell}$$
is the temperature of the solar cell, which is affected by temperature, radiation and wind speed; Tas_{STC} is the ambient air temperature under standard atmospheric pressure, Tas_{STC}=25° C.;
$${I}_{{n}_{pv}}^{pv}$$
is the installed capacity of the photovoltaic power station;
$${Tas}_{{n}_{pv} , t}^{cell} = {c}_{{n}_{pv}}^{0} + {c}_{{n}_{pv}}^{1} \cdot {Tas}_{{n}_{pv} , t} + {c}_{{n}_{pv}}^{2} \cdot {rsds}_{{n}_{pv} , t} + {c}_{{n}_{pv}}^{3} \cdot {V}_{{n}_{pv} , t} \qquad ( 12 )$$
wherein
$${c}_{{n}_{pv}}^{0} = 4.3 ° C . , {c}_{{n}_{pv}}^{1} = 0.943 , {c}_{{n}_{pv}}^{2} = 0.028 ° C . \cdot {m}^{2} \cdot {W}^{- 1} , {c}_{{n}_{pv}}^{3} = - 1.528 ° C . \cdot s \cdot {m}^{- 1} ; {Tas}_{{n}_{pv} , t}$$
is the ambient temperature at the photovoltaic power station nₚᵥ, ° C.; Vₙ_{ₚᵥ}_{,t} is the surface wind speed at the photovoltaic power station nₚᵥ, m/s:
(4) the hydrological and meteorological variables at each power station are taken as the characteristic input; the piecewise linear fitting method is adopted to construct the linkage equation for the consumption of hydropower, wind power and photovoltaic power, realizing the extraction of the complementary consumption relationship of hydropower, wind power and photovoltaic power; the specific expression is as follows:
$${\sum }_{{n}_{w} = 1}^{{N}_{w}} {N}_{{n}_{w} , m}^{w} + {\sum }_{{n}_{pv} = 1}^{{N}_{pv}} {N}_{{n}_{pv} , m}^{pv} = {f}_{{U}_{t}^{{load}_{u}}} ( {\sum }_{{n}_{h} = 1}^{{N}_{h}} {N}_{{n}_{h} , m}^{h} ) \qquad ( 13 )$$
where
$${f}_{{U}_{m}}^{{load}_{u} ( )}$$
represents the linkage function of hydropower, wind power, and photovoltaic power consumption, indicating the quantitative relationship of hydropower, wind power and photovoltaic power consumption in the scenario where the load is
$${U}_{m}^{{load}_{u}}$$
in month m; the Gurobi solver is taken as the modeling platform; the Python language is used to transform the above nonlinear model into a mixed integer linear programming; the influence relationship between the hydropower generation and the consumption scale of wind and photovoltaic power is determined; the specific influence includes four main stages:
Stage 1: insufficient regulation capacity of hydropower restricts the consumption of wind and photovoltaic power; with the increase of hydropower generation, the flexibility of hydropower is enhanced, and the proportion of wind and photovoltaic power consumption shows an upward trend;
Stage 2: the hydropower regulation capacity can completely smooth out the fluctuations in wind and photovoltaic power generation and respond to the peak shaving demands of power grids; thus, wind and solar resources can be fully consumed by power grids;
Stage 3: the channel capacity limits the bundled transmission generation of hydropower, wind and photovoltaic power; thus, the proportion of wind and photovoltaic power consumption shows a downward trend with the increase of hydropower generation;
Stage 4: the hydropower generation will continue to increase until the capacity limit of the channel is exceeded, and the wind and solar photovoltaic power generation will no longer be able to be consumed.
